(19) United States
(12) Patent Application Publication
(10) Pub. No.: US 2013/0341709 A1
(43) Pub. Date: Dec. 26, 2013

(54) SEMICONDUCTOR DEVICE WITH ELECTRODE INCLUDING INTERVENTION FILM

(71) Applicant: Elpida Memory, Inc., Tokyo (JP)

(72) Inventor: Masanori KIKUCHI, Tokyo (JP)

(21) Appl. No.: 13/919,623

(22) Filed: Jun. 17, 2013

(30) Foreign Application Priority Data
Jun. 21, 2012 (JP) 2012-139711

(51) Int. Cl. H01L 29/78; H01L 29/06

(52) U.S. Cl. CPC H01L 29/7827; H01L 29/0642
USPC 257/330; 257/506

(57) ABSTRACT

In a semiconductor device including a semiconductor substrate, a trench formed on the semiconductor substrate, an insulating film formed on a side wall of the trench, and an electrode formed on the insulating film. The electrode includes a first film made of first metal nitride, an intervention film made of silicon or of second metal silicide, and a second film made of third metal in this order.

This application is based upon and claims the benefit of priority from Japanese patent application No. 2012-139711, filed on Jun. 21, 2012, the disclosure of which is incorporated herein in its entirety by reference.

### BACKGROUND OF THE INVENTION

1. Field of the Invention

The present invention relates to a semiconductor device, and more particularly to a semiconductor device including a plurality of recessed gate transistors formed on a semiconductor substrate.

2. Description of Related Art

In recent years, in a field of semiconductor devices, for example, such as DRAM (Dynamic Random Access Memory) elements, high integration has been improved due to a high extension of equipment in which the semiconductor devices are used and so on.

In addition, with the miniaturization of transistors provided in such as semiconductor devices, degrading of transistor characteristics due to short channel effect and increasing of contact resistance due to a reduction in diameters of contact holes become problems.

To solve the above-mentioned problems and to further improve the miniaturization, proposal has been made to adopt, as cell transistors constituting memory cells, recessed gate transistors having gate electrodes which are buried in a surface layer of a semiconductor substrate.

Conventionally, stacked structure of a titanium nitride (TiN) film and a tungsten (W) film by means of a CVD (Chemical Vapor Deposition) method is used as an electrode material of a buried gate electrode of the DRAM (e.g. see, Japanese Laid-Open Patent Publication No. 2011-192800, U.S. Pat. No. 8,309,425, and US Patent Application Publication No. 2008/0081453).

However, with improving of the miniaturization, resistance of the buried gate electrode increases, the problem arises because a switching rate of a memory device is delayed.

### SUMMARY

According to a first aspect of the present invention, there is provided a semiconductor device comprising: a semiconductor substrate; a trench formed on the semiconductor substrate; an insulating film formed on a side wall of the trench; and an electrode formed on the insulating film, the electrode comprising a first film made of a first metal which is nitrided, an intervention film made of a silicon or of a second metal which is silicided, and a second film made of a third metal in this order.

### BRIEF DESCRIPTION OF THE DRAWINGS

The above features and advantages of the present invention will be more apparent from the following of certain preferred embodiments taken in conjunction with the accompanying drawings, in which:

FIG. 1A is a plan view illustrating a first manufacturing step in a process for manufacturing a semiconductor device according to a first exemplary embodiment of this invention;

FIG. 1B is a cross-sectional view taken along line X1-X1 shown in FIG. 1A;

FIG. 10 is a cross-sectional view taken along line X2-X2 shown in FIG. 1A;

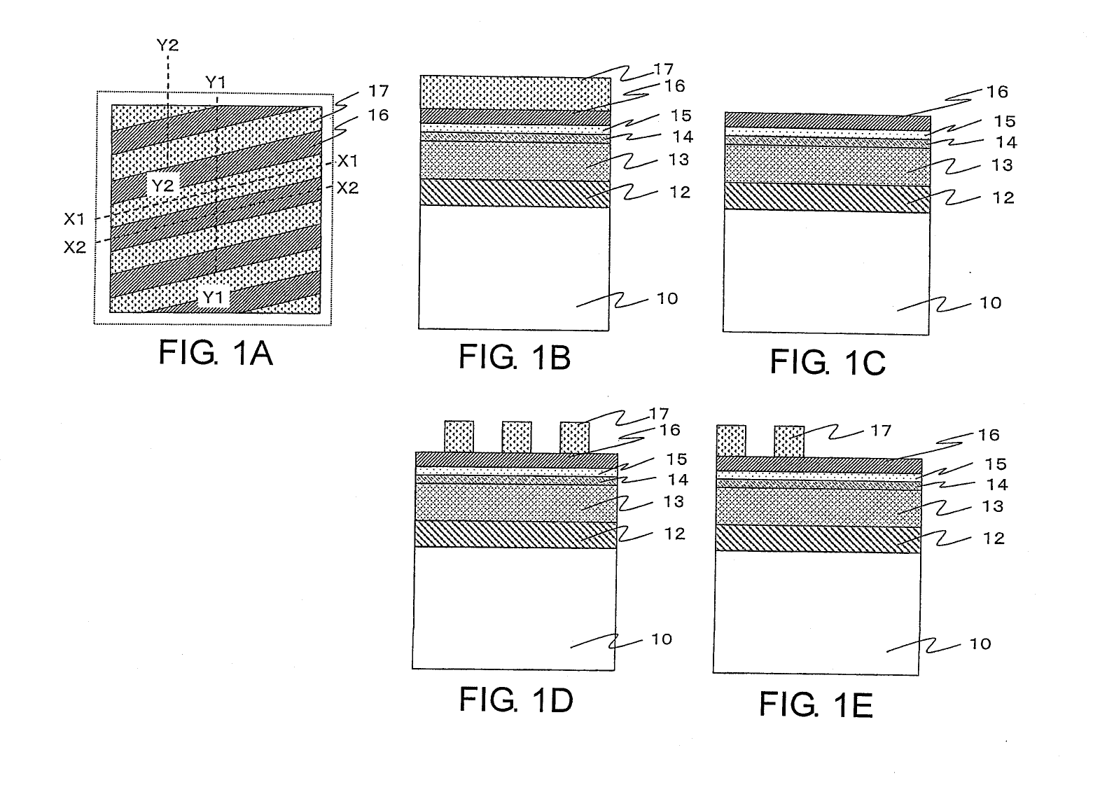

FIG. 1D is a cross-sectional view taken along line Y1-Y1 shown in FIG. 1A;

FIG. 1E is a cross-sectional view taken along line Y2-Y2 shown in FIG. 1A;

FIG. 2A is a plan view illustrating a second manufacturing step in the process for manufacturing the semiconductor device according to the first exemplary embodiment of this invention;

FIG. 2B is a cross-sectional view taken along line X1-X1 shown in FIG. 2A;

FIG. 2C is a cross-sectional view taken along line X2-X2 shown in FIG. 2A;

FIG. 2D is a cross-sectional view taken along line Y1-Y1 shown in FIG. 2A;

FIG. 2E is a cross-sectional view taken along line Y2-Y2 shown in FIG. 2A;

FIG. 3A is a plan view illustrating a third manufacturing step in the process for manufacturing the semiconductor device according to the first exemplary embodiment of this invention;

FIG. 3B is a cross-sectional view taken along line X1-X1 shown in FIG. 3A;

FIG. 3C is a cross-sectional view taken along line X2-X2 shown in FIG. 3A;

FIG. 3D is a cross-sectional view taken along line Y1-Y1 shown in FIG. 3A;

FIG. 3E is a cross-sectional view taken along line Y2-Y2 shown in FIG. 3A;

FIG. 4A is a plan view illustrating a fourth manufacturing step in the process for manufacturing the semiconductor device according to the first exemplary embodiment of this invention;

FIG. 4B is a cross-sectional view taken along line X1-X1 shown in FIG. 4A;

FIG. 4C is a cross-sectional view taken along line X2-X2 shown in FIG. 4A;

FIG. 4D is a cross-sectional view taken along line Y1-Y1 shown in FIG. 4A;

FIG. 4E is a cross-sectional view taken along line Y2-Y2 shown in FIG. 4A;

FIG. 5A is a plan view illustrating a fifth manufacturing step in the process for manufacturing the semiconductor device according to the first exemplary embodiment of this invention;

FIG. 5B is a cross-sectional view taken along line X1-X1 shown in FIG. 5A;

FIG. 5C is a cross-sectional view taken along line X2-X2 shown in FIG. 5A;

FIG. 5D is a cross-sectional view taken along line Y1-Y1 shown in FIG. 5A;

FIG. 5E is a cross-sectional view taken along line Y2-Y2 shown in FIG. 5A;

FIG. 6A is a plan view illustrating a sixth manufacturing step in the process for manufacturing the semiconductor device according to the first exemplary embodiment of this invention;

FIG. 6B is a cross-sectional view taken along line X1-X1 shown in FIG. 6A;

FIG. 6C is a cross-sectional view taken along line X2-X2 shown in FIG. 6A;

FIG. 6D is a cross-sectional view taken along line Y1-Y1 shown in FIG. 6A;

FIG. 6E is a cross-sectional view taken along line Y2-Y2 shown in FIG. 6A;

FIG. 7A is a plan view illustrating a seventh manufacturing step in the process for manufacturing the semiconductor device according to the first exemplary embodiment of this invention;

FIG. 7B is a cross-sectional view taken along line X1-X1 shown in FIG. 7A;

FIG. 7C is a cross-sectional view taken along line X2-X2 shown in FIG. 7A;

FIG. 7D is a cross-sectional view taken along line Y1-Y1 shown in FIG. 7A;

FIG. 7E is a cross-sectional view taken along line Y2-Y2 shown in FIG. 7A;

FIG. 8 is a cross-sectional view illustrating an eighth manufacturing step in the process for manufacturing the semiconductor device according to the first exemplary embodiment of this invention;

FIG. 9 is a cross-sectional view illustrating a ninth manufacturing step in the process for manufacturing the semiconductor device according to the first exemplary embodiment of this invention;

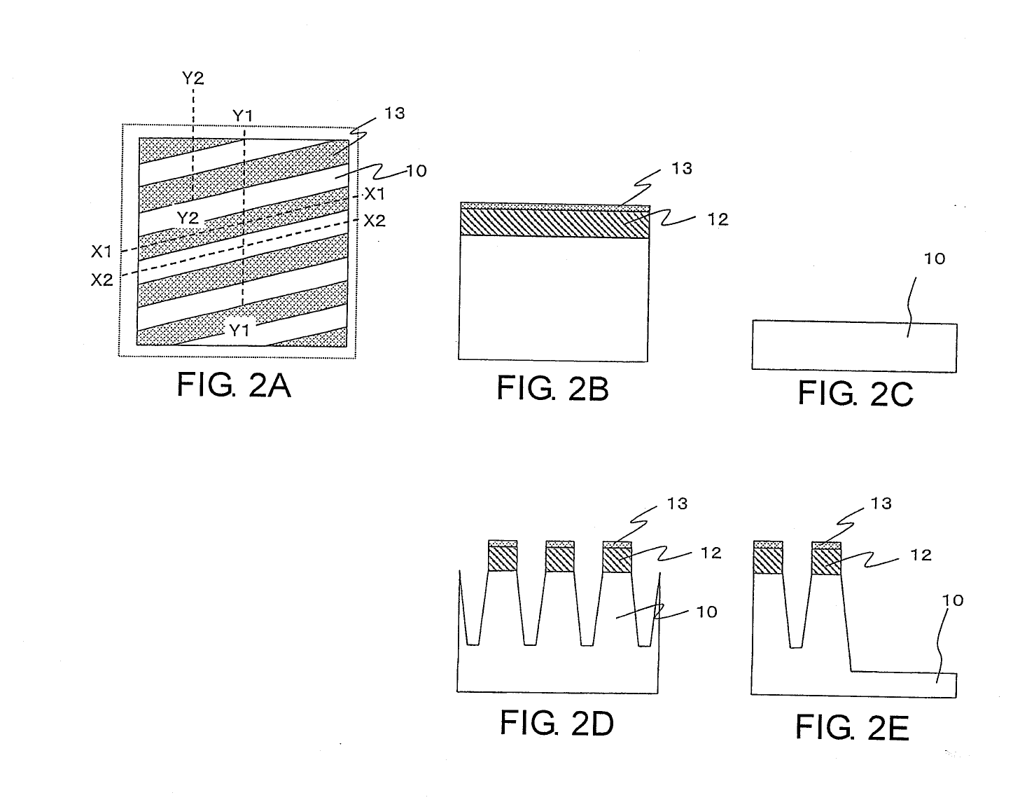

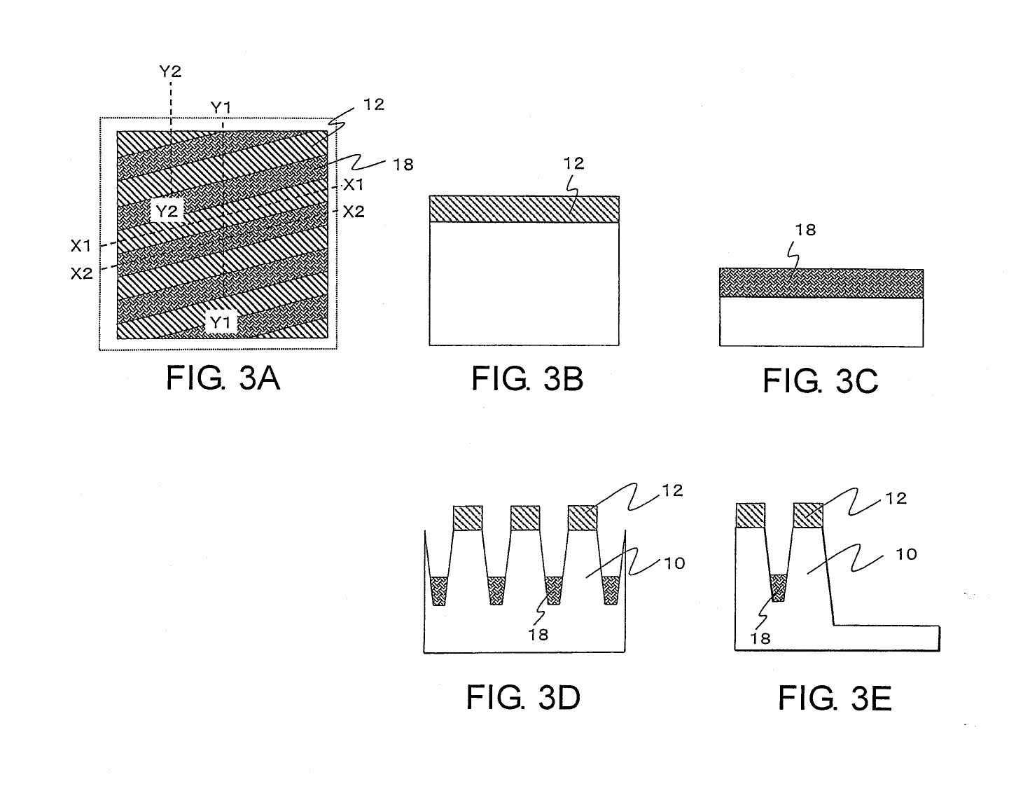

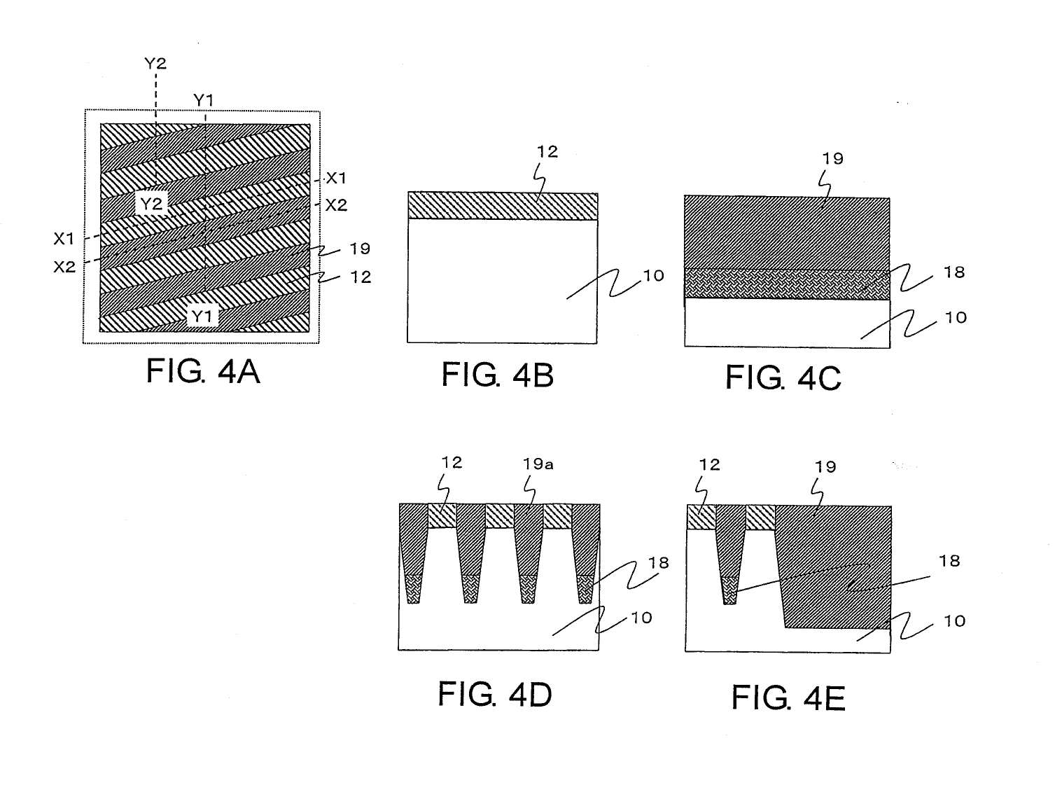

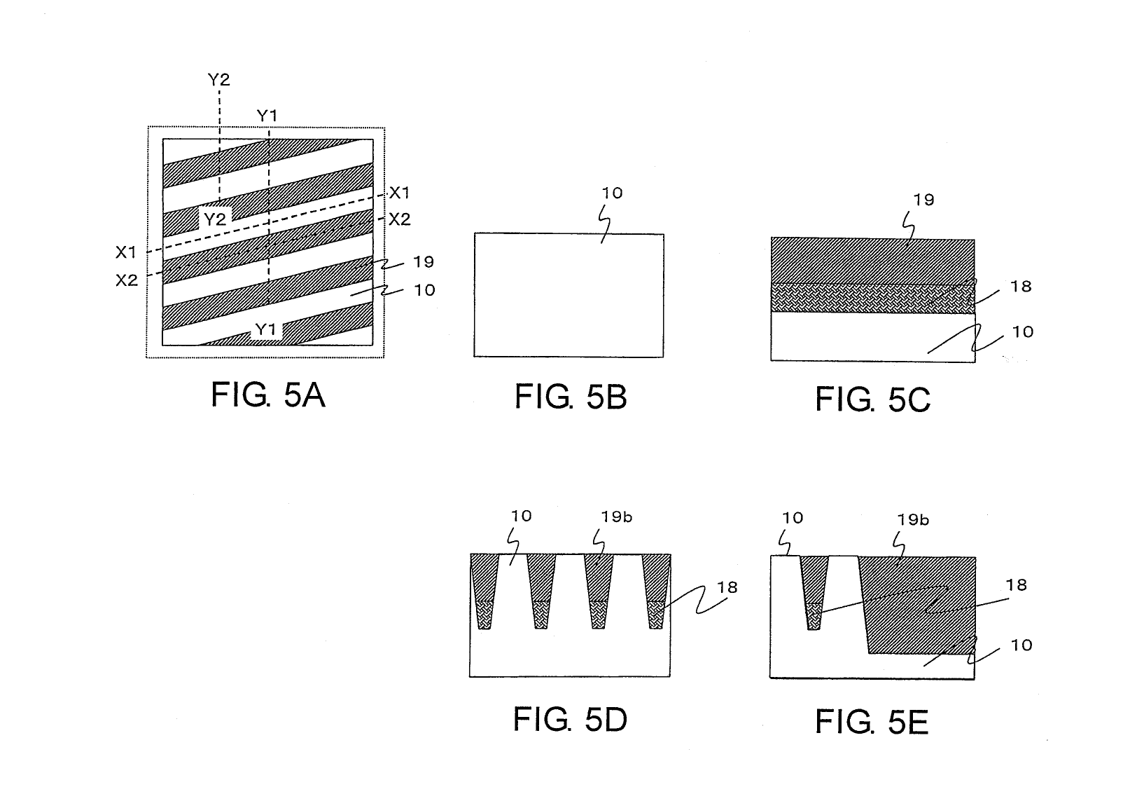

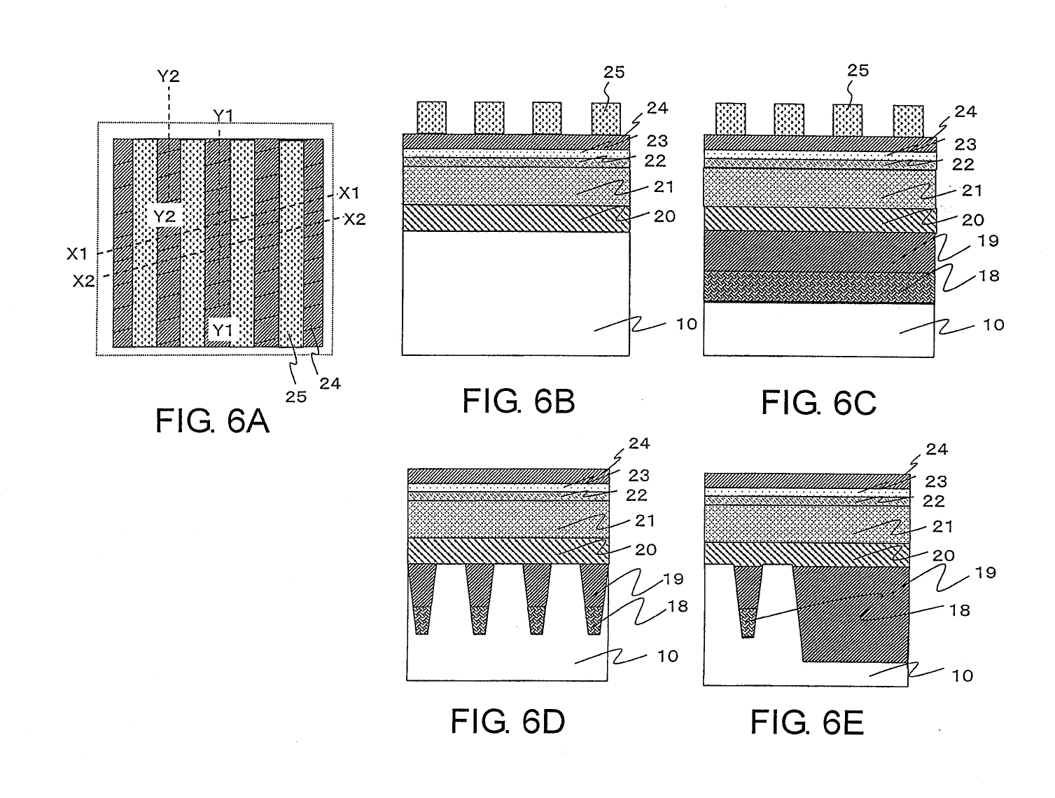

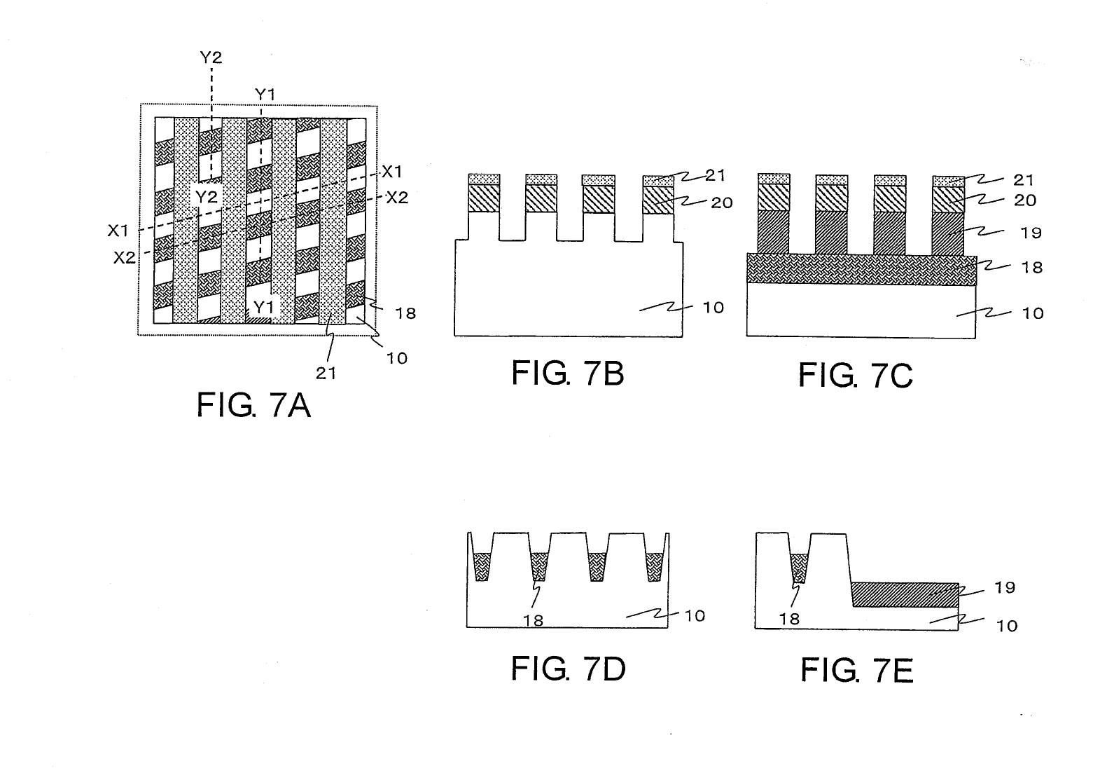

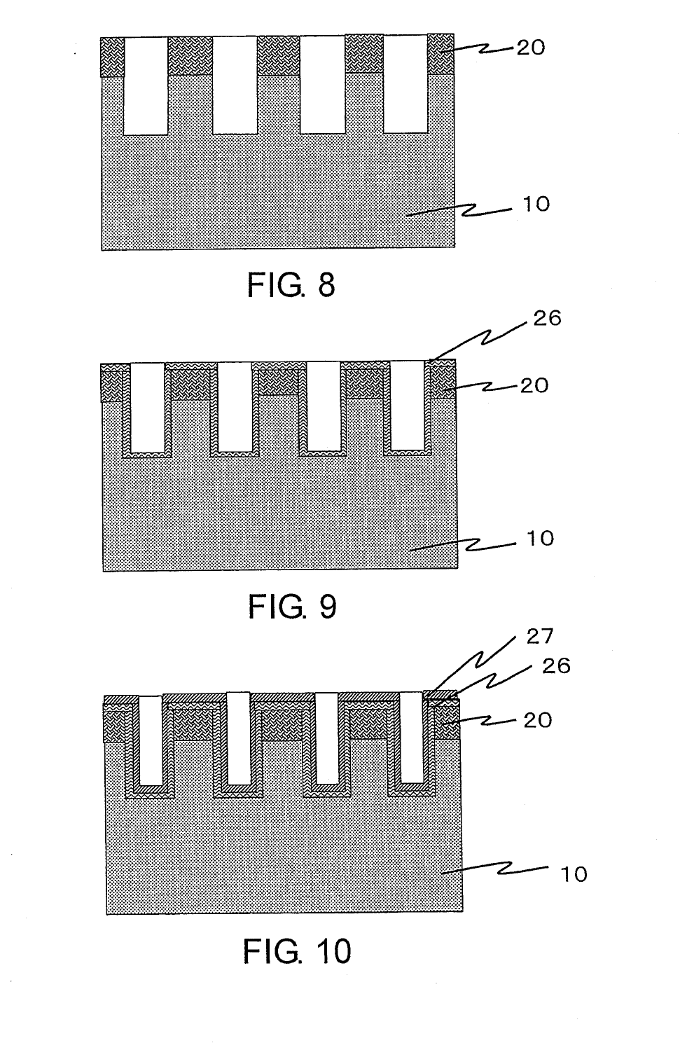

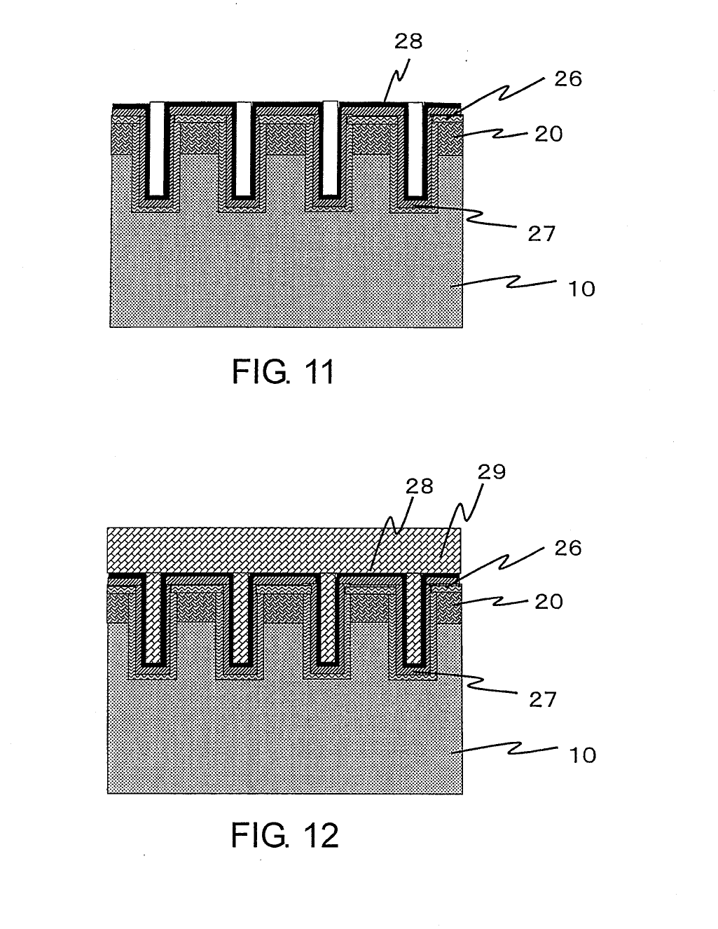

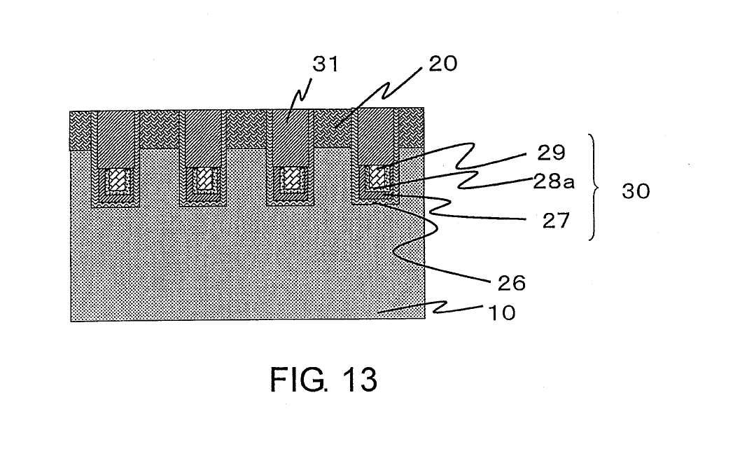

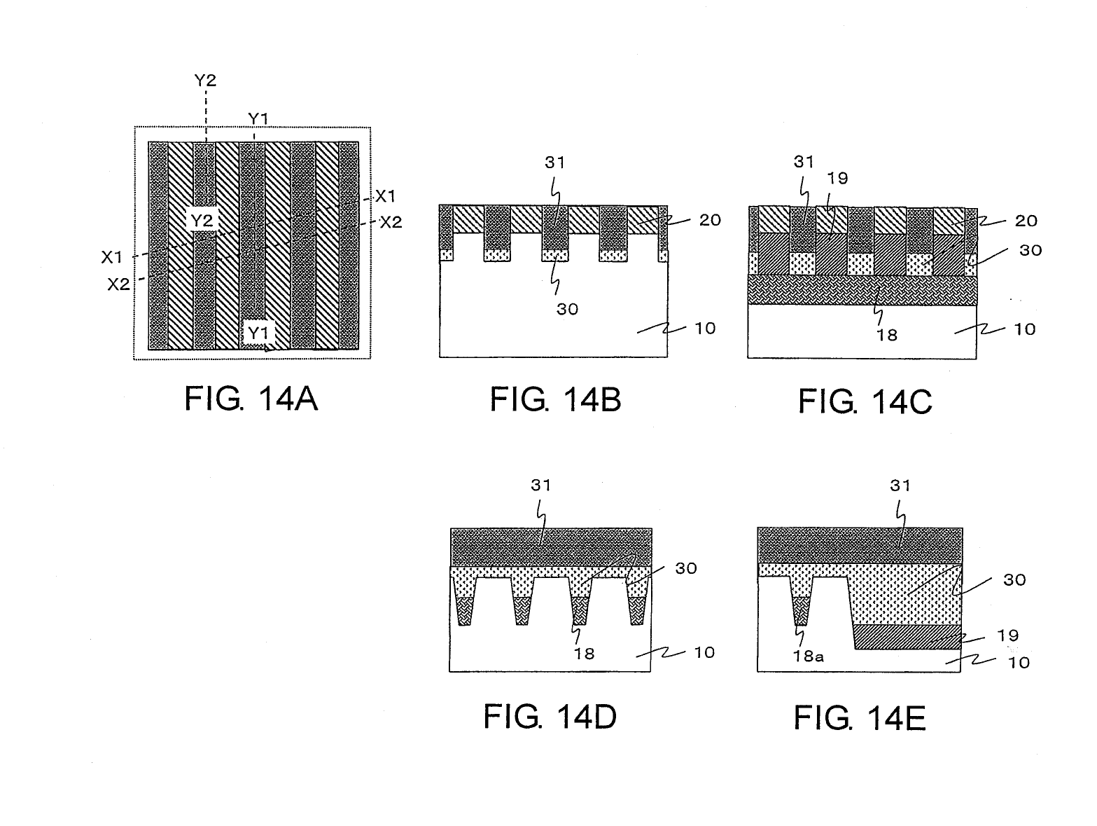

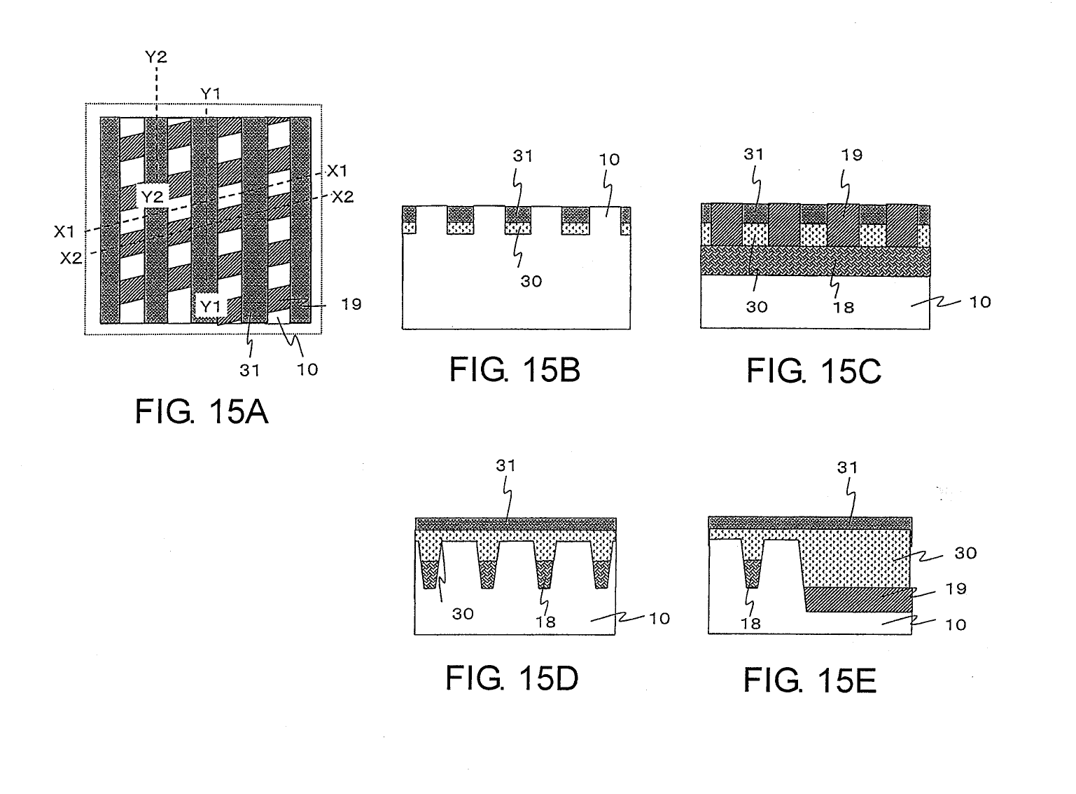

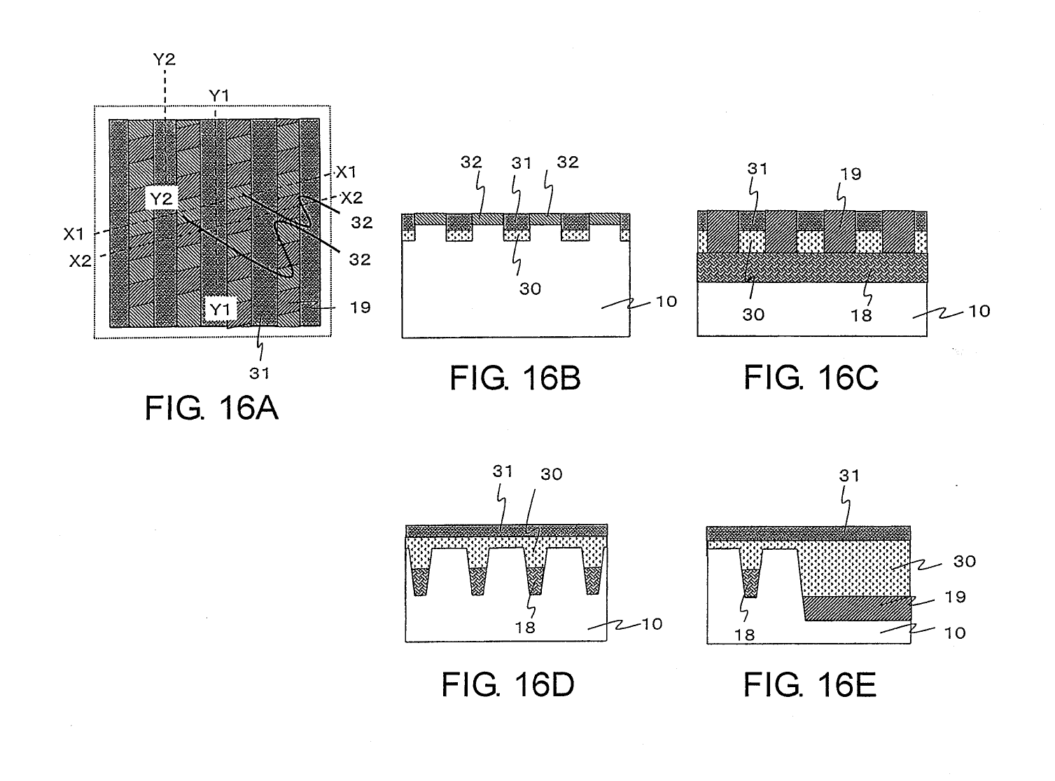

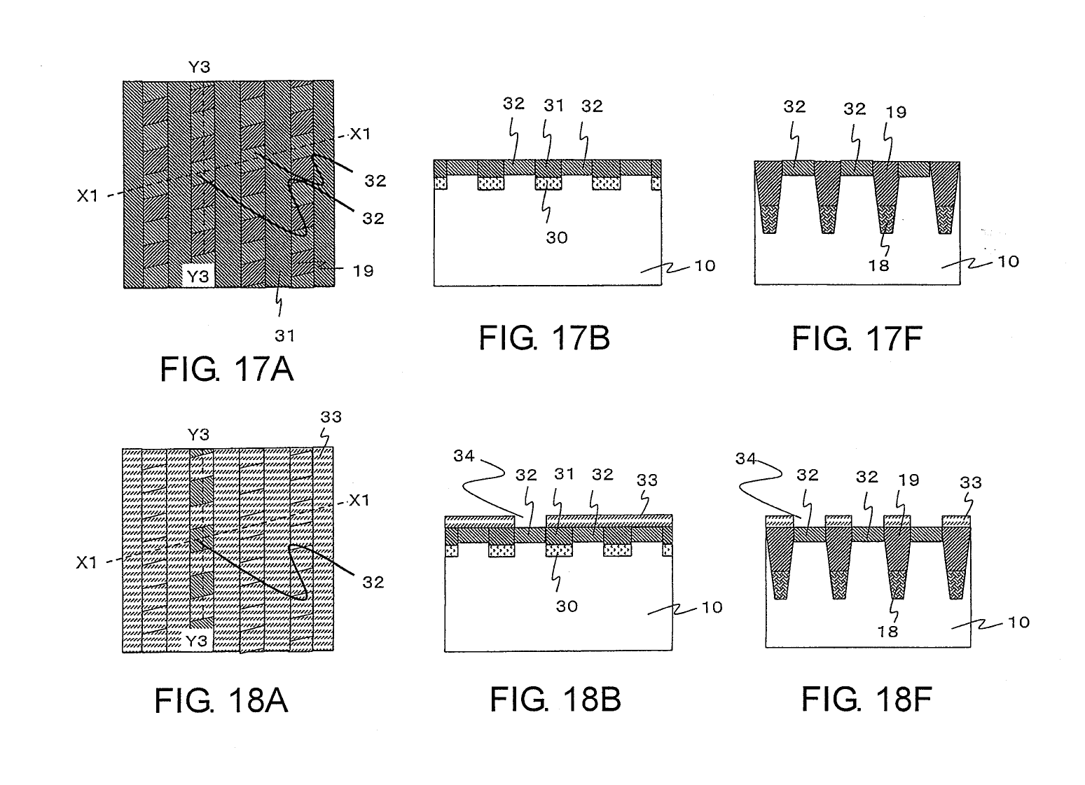

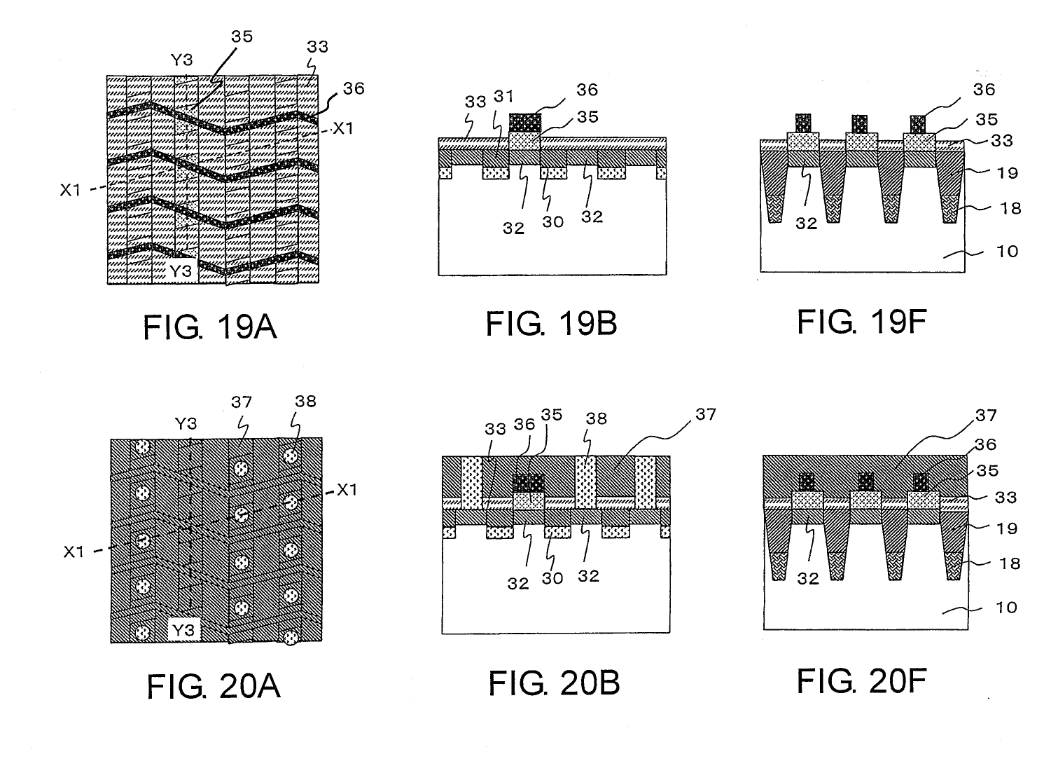

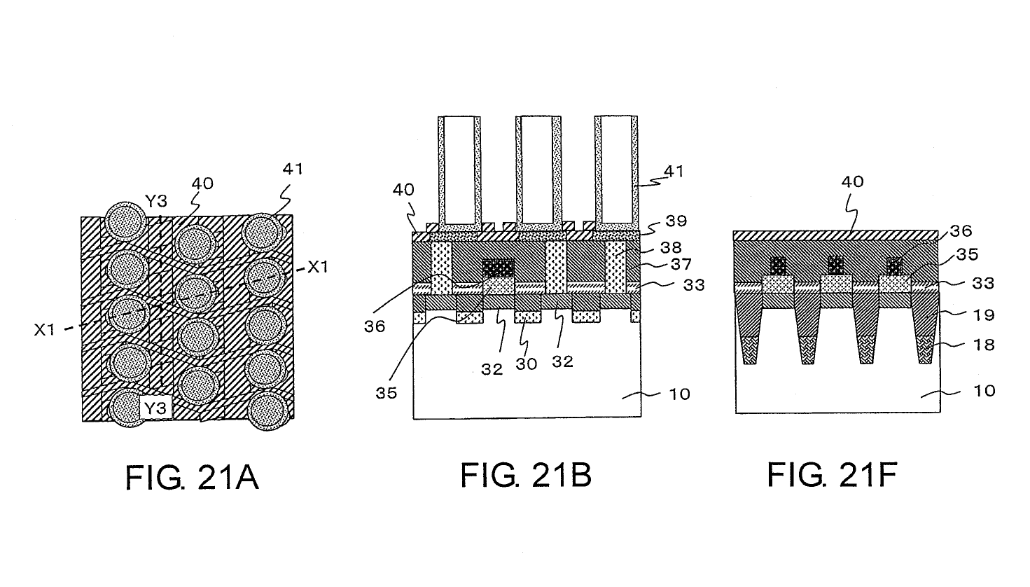

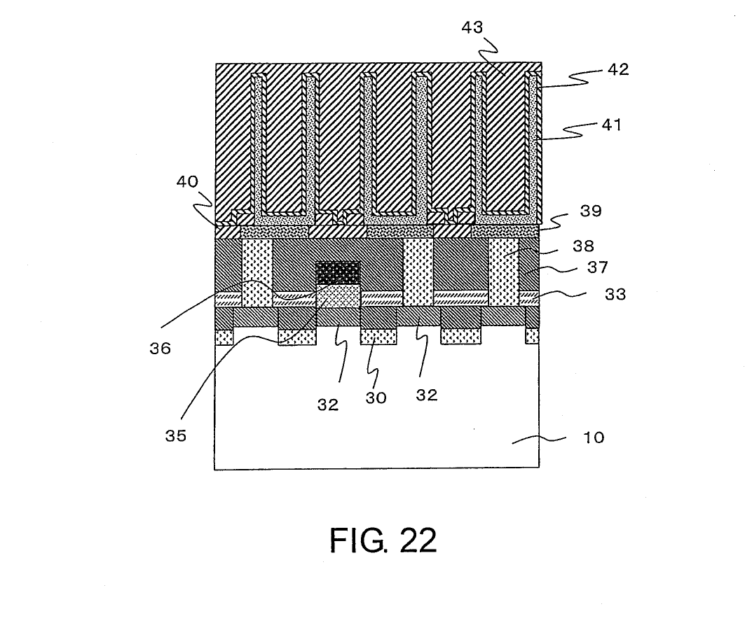

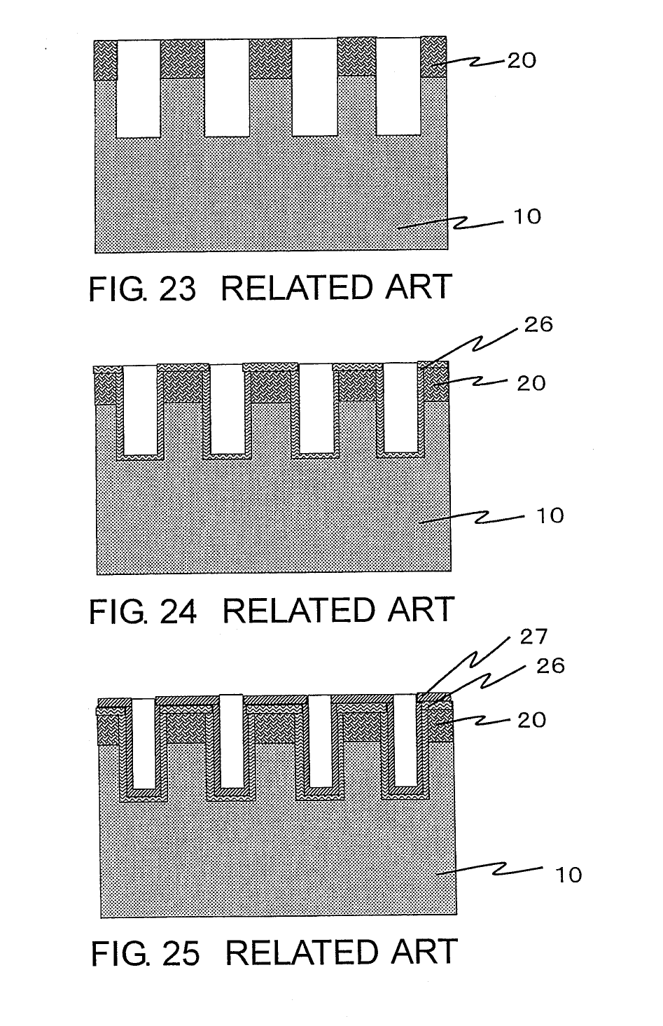

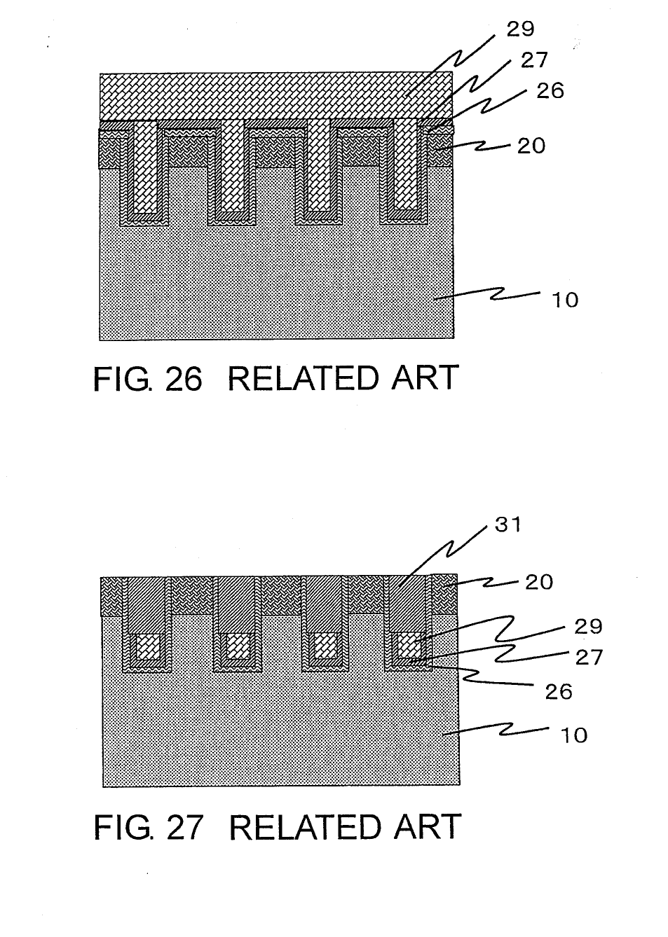

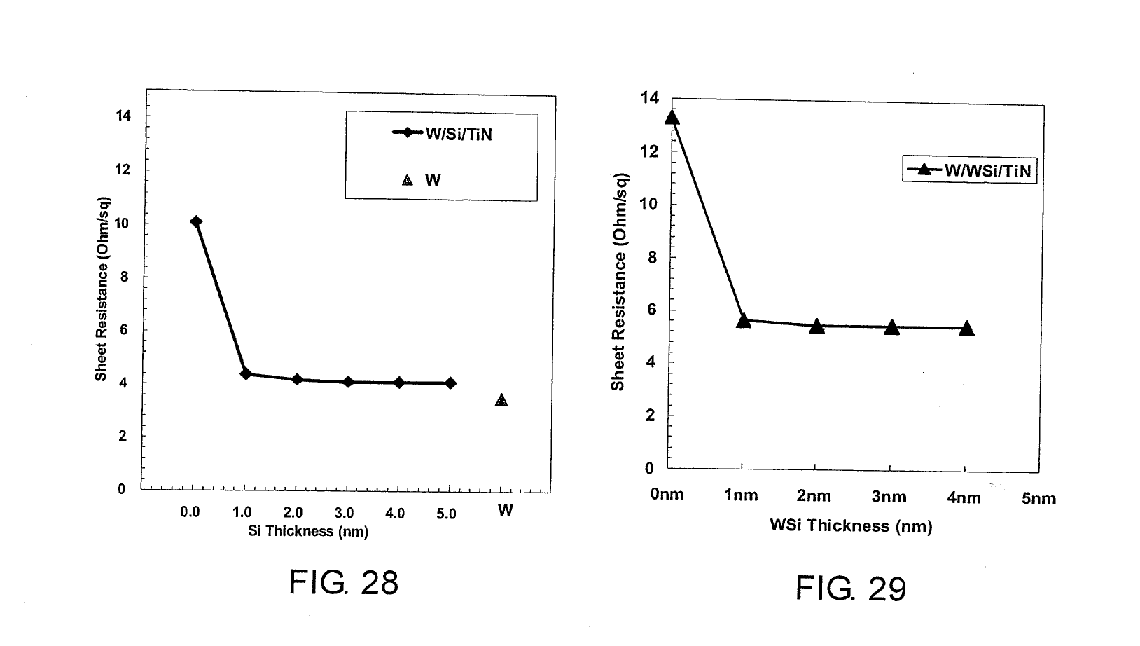

FIG. 10 is a cross-sectional view illustrating a tenth manufacturing step in the process for manufacturing the semiconductor device according to the first exemplary embodiment of this invention;

FIG. 11 is a cross-sectional view illustrating an eleventh manufacturing step in the process for manufacturing the semiconductor device according to the first exemplary embodiment of this invention;

FIG. 12 is a cross-sectional view illustrating a twelfth manufacturing step in the process for manufacturing the semiconductor device according to the first exemplary embodiment of this invention;

FIG. 13 is a cross-sectional view illustrating a thirteenth manufacturing step in the process for manufacturing the semiconductor device according to the first exemplary embodiment of this invention;

FIG. 14A is a plan view illustrating a fourteenth manufacturing step in the process for manufacturing the semiconductor device according to the first exemplary embodiment of this invention;

FIG. 14B is a cross-sectional view taken along line X1-X1 shown in FIG. 14A;

FIG. 4C is a cross-sectional view taken along line X2-X2 shown in FIG. 4A;

FIG. 14D is a cross-sectional view taken along line Y1-Y1 shown in FIG. 14A;

FIG. 14E is a cross-sectional view taken along line Y2-Y2 shown in FIG. 14A;

FIG. 15A is a plan view illustrating a fifteenth manufacturing step in the process for manufacturing the semiconductor device according to the first exemplary embodiment of this invention;

FIG. 15B is a cross-sectional view taken along line X1-X1 shown in FIG. 15A;

FIG. 15C is a cross-sectional view taken along line X2-X2 shown in FIG. 15A;

FIG. 15D is a cross-sectional view taken along line Y1-Y1 shown in FIG. 15A;

FIG. 15E is a cross-sectional view taken along line Y2-Y2 shown in FIG. 15A;

FIG. 16A is a plan view illustrating a sixteenth manufacturing step in the process for manufacturing the semiconductor device according to the first exemplary embodiment of this invention;

FIG. 16B is a cross-sectional view taken along line X1-X1 shown in FIG. 16A;

FIG. 16C is a cross-sectional view taken along line X2-X2 shown in FIG. 16A;

FIG. 16D is a cross-sectional view taken along line Y1-Y1 shown in FIG. 16A;

FIG. 16E is a cross-sectional view taken along line Y2-Y2 shown in FIG. 16A;

FIG. 17A is a plan view illustrating the sixteenth manufacturing step in the process for manufacturing the semiconductor device according to the first exemplary embodiment of this invention;

FIG. 17B is a cross-sectional view taken along line X1-X1 shown in FIG. 17A;

FIG. 17F is a cross-sectional view taken along line Y3-Y3 shown in FIG. 17A;

FIG. 18A is a plan view illustrating a seventeenth manufacturing step in the process for manufacturing the semiconductor device according to the first exemplary embodiment of this invention;

FIG. 18B is a cross-sectional view taken along line X1-X1 shown in FIG. 18A;

FIG. 18F is a cross-sectional view taken along line Y3-Y3 shown in FIG. 18A;

FIG. 19A is a plan view illustrating an eighteenth manufacturing step in the process for manufacturing the semiconductor device according to the first exemplary embodiment of this invention;

FIG. 19B is a cross-sectional view taken along line X1-X1 shown in FIG. 19A;

FIG. 19F is a cross-sectional view taken along line Y3-Y3 shown in FIG. 19A;

FIG. 20A is a plan view illustrating a nineteenth manufacturing step in the process for manufacturing the semiconductor device according to the first exemplary embodiment of this invention;

FIG. 20B is a cross-sectional view taken along line X1-X1 shown in FIG. 20A;

FIG. 20F is a cross-sectional view taken along line Y3-Y3 shown in FIG. 20A;

FIG. 21A is a plan view illustrating a twentieth manufacturing step in the process for manufacturing the semiconductor device according to the first exemplary embodiment of this invention;

FIG. 21B is a cross-sectional view taken along line X1-X1 shown in FIG. 21A;

FIG. 21F is a cross-sectional view taken along line Y3-Y3 shown in FIG. 21A;

FIG. 22 is a cross-sectional view illustrating a twenty-first manufacturing step in the process for manufacturing the semiconductor device according to the first exemplary embodiment of this invention;

FIG. 23 is a cross-sectional view illustrating an eighth manufacturing step in a process for manufacturing a semiconductor device of a related art;

FIG. 24 is a cross-sectional view illustrating a ninth manufacturing step in the process for manufacturing the semiconductor device of the related art;

FIG. 25 is a cross-sectional view illustrating a tenth manufacturing step in the process for manufacturing the semiconductor device of the related art;

FIG. 26 is a cross-sectional view illustrating an eleventh manufacturing step in the process for manufacturing the semiconductor device of the related art;

FIG. 27 is a cross-sectional view illustrating a twelfth manufacturing step in the process for manufacturing the semiconductor device of the related art;

FIG. 28 is a view illustrating a relationship between a thickness of an amorphous silicon film and a sheet resistance; and

FIG. 29 is a view illustrating a relationship between a thickness of a tungsten silicide film and sheet resistance.

### DETAILED DESCRIPTION OF THE EMBODIMENTS

### Related Art

Before describing the present invention, the related art will be explained in detail with reference to FIGS. 23 to 27 in order to facilitate the understanding the present invention.

FIGS. 23 to 27 are cross-sectional views illustrating a flow of forming buried gate electrodes of the related art and illustrate manufacturing steps from forming of buried gate electrode trenches to forming of cap insulating films on the buried gate electrodes. Herein, in order to simplify the description, the description from a first manufacturing step to a seventh manufacturing step is omitted and the description will be made about a manufacturing flow after an eighth manufacturing step.

FIG. 23 shows a state where an amorphous carbon film (not shown) is removed and buried gate electrode trenches are formed. A silicon nitride film 20 is formed on a semiconductor substrate 10. By selectively removing a surface (silicon) of the semiconductor substrate 10 alone, the buried gate electrode trenches are formed.

Subsequently, as shown in FIG. 24, by oxidizing an surface of the buried gate electrode trenches exposed from opening portions of a mask layer by means of thermal oxidation (ISSG: In Site Steam Generation), a gate insulating film 26 consisting of a silicon oxide film is formed thereon.

Thereafter, as shown in FIG. 25, a titanium nitride (TiN) film 27 is deposited. Subsequently, as shown in FIG. 26, a tungsten (W) film 29 is deposited. Therefore, a conductive film in which the titanium nitride (TiN) film 27 and the tungsten (W) film 29 are stacked in order is formed over the entire surface of the semiconductor substrate 10.

Next, as shown in FIG. 27, an upper surface of the conductive film is polished by a CMP (Chemical Mechanical Polishing) process until an upper surface of the above-mentioned silicon nitride film 20 serving as a stopper is exposed.

Then, the conductive film, which fills the above-mentioned gate electrode trenches, is etched to cause the conductive film to remain in the trenches.

Subsequently, as shown in FIG. 27, a cap insulating film 31 is formed over the entire surface of the semiconductor substrate 10. A BPSG (Boron-doped Phospho-Silicate Glass) film is used as the cap insulating film 31. Therefore, the buried gate electrodes each of which comprises a titanium nitride (TiN)/tungsten (W) stacked film are formed. Thereafter, an upper surface of the cap insulating film (BPSG film) 31 is polished by a CMP (Chemical Mechanical Polishing) process until the upper surface of the above-mentioned silicon nitride film 20 serving as the stopper is exposed.

Now, the description will proceed to problems of the related art.

In forming of the tungsten (W) film 29, in dependence on fine pillar crystals of the titanium nitride (TiN) film 27 acting as a barrier film, crystals of the tungsten (W) film 29 also become fine, and a resistance value of the tungsten (W) film 29 becomes higher than that of a tungsten (W) film in bulk.

Consequently, the present inventor made a study of forming the tungsten (W) film 29 as a low-resistance film in order to resolve this problem.

As a result of carrying out an experiment over and over again, the present inventor confirmed that the resistance value of the tungsten (W) film 29 becomes substantially equal to that of the tungsten (W) film in bulk when the tungsten (W) film 29 is formed over the titanium nitride (TiN) film 27 acting as the barrier film through the mediation of a thin silicon film or of a thin silicide film.

FIG. 28 illustrates a relationship between a thickness of the silicon film and a sheet resistance in a case where the titanium nitride (TiN) film, the silicon film, and the tungsten (W) film are formed in this order and thicknesses of the titanium nitride (TiN) film and the tungsten (W) film are fixed. FIG. 28 shows that the sheet resistance dramatically decreases and is equal to that of the tungsten (W) film in bulk if the thickness of the silicon film is not less than 1 nm.

FIG. 29 illustrates a relationship between a thickness of a tungsten silicide film and a sheet resistance in a case where the titanium nitride (TiN) film, the tungsten silicide film, and the tungsten (W) film are formed in this order and thicknesses of the titanium nitride (TiN) film and the tungsten (W) film are fixed. From FIG. 29, it is understood that the sheet resistance dramatically decreases by inserting the tungsten silicide film having a thickness which is not less than 1 nm.

In the manner which is illustrated in the above-mentioned US Patent Application Publication No. 2008/0081453, it is generally known in the art that resistance of a tungsten (W) film is dependent on a grain size of this film.

The above-mentioned phenomena are estimated as follows. Specifically, inasmuch as a ground immediately below the tungsten (W) film becomes amorphous in the both cases, the tungsten (W) film is originally crystallized independent on crystal of the ground. As a result, a size of the crystal becomes relatively large in comparison with a case where a ground immediately below it is titanium nitride. This invention applies this film forming method and this film forming structure to form buried gate electrodes.

In recent years, the buried gate electrodes are miniaturized. If the silicon film or the tungsten silicide film stacked on the titanium nitride (TiN) film is excessively thick, it is feared that any space for stacking tungsten (W) films thereon cannot be ensured in buried gate electrode trenches. For that reason, it is convenient that the silicon film or a silicide film stacked on the titanium nitride (TiN) film has a thickness of the order of 1 nm to 3 nm.

### First Exemplary Embodiment

Now, the description will be described about exemplary embodiments to which this invention is applied with reference to drawings. Drawings used in the following description are for describing configurations of the exemplary embodiments of this invention, and therefore sizes, thicknesses, dimensions, or the like of respective parts illustrated may be different from relationships of actual sizes.

### (Method of Manufacturing a Semiconductor Device)

FIGS. 1A through 22 illustrate flow views from for forming element separation to for forming a capacitor through buried gate electrodes in manufacturing steps of a semiconductor device according to a first exemplary embodiment of this invention.

FIGS. 1A, 2A, 3A, 4A, 5A, 6A, 7A, 14A, 15A, and 16A are plan views, FIGS. 1B, 2B, 3B, 4B, 5B, 6B, 7B, 14B, 15B, and 16B are cross-sectional views taken along line X1-X1, FIGS. 10, 2C, 3C, 4C, 5C, 6C, 7C, 14C, 15C, and 16C are cross-sectional views taken along line X2-X2, FIGS. 1D, 2D, 3D, 4D, 5D, 6D, 7D, 14D, 15D, and 16D are cross-sectional views taken along line Y1-Y1, and FIGS. 1E, 2E, 3E, 4E, 5E, 6E, 7E, 14E, 15E, and 16E are cross-sectional views taken along line Y2-Y2. In addition, FIGS. 8 to 13 and 22 are cross-sectional views. Furthermore, FIGS. 17A, 18A, 19A, 20A, and 21A are plan views, FIGS. 17B, 18B, 19B, 20B, and 21B are cross-sectional views taken along line X1-X1, and FIGS. 17F, 18F, 19F, 20F, and 21F are cross-sectional views taken along line Y3-Y3.

First, referring to FIGS. 1A to 1E, a first mask layer is formed on a semiconductor substrate 10. The first mask layer comprises a first silicon nitride film 12, a first amorphous carbon film 13, a first silicon oxynitride film 14, a first silicon oxide film 15, and a first anti-reflective (BARC) film 16 which are stacked over in order. After a first photoresist (PR) 17 is formed over the first mask layer, a first resist pattern 17 having a shape corresponding to an active region is formed while the photoresist 17 is patterned by a lithography process. The first resist pattern 17 has openings at positions corresponding to element isolation regions and an opening at a position corresponding to a peripheral region.

Subsequently, as shown in FIGS. 2A to 2E, the first mask layer is patterned by an anisotropic dry etching process with the first resist pattern 17. At this time, although the first resist pattern 17 is removed from the first mask layer with the progression of the dry etching process, the shape of the first resist pattern 17 is transferred onto the first mask layer. Therefore, the first mask layer is also removed with the progression of the dry etching process while the shape of the transferred from an upper layer to a lower layer. For this reason, when the patterning of the first mask layer finishes, all of the first anti-reflective (BARC) film 16, the first silicon oxide film 15, and the first silicon oxynitride film 14 are perfectly removed. The first mask layer, which includes the patterned first amorphous carbon film 13 and the patterned silicon nitride film 12, remains so that the first mask layer has the opening portions at the positions corresponding to the above-mentioned element isolation regions and the opening at the position corresponding to the above-mentioned peripheral region.

Then, as shown in FIGS. 2A to 2E, the surface of the semiconductor substrate 10 is patterned by an anisotropic dry etching process with the patterned first mask layer. Thus, the shape of the first mask layer is transferred onto the surface of the semiconductor substrate 10, multiple element isolation grooves extending the first direction are formed in a cell array region of the semiconductor substrate 10.

When the element isolation grooves are formed, a groove, which is deeper than the groove in the cell array region, is formed in the peripheral region outside the cell array region using the micro-loading effect. Specifically, the groove in the peripheral region has a larger horizontal width than that of the groove in the cell array region. The depth of the above-mentioned groove is such that a second silicon oxide film 19 (which will later be described with FIG. 7E) filling the above-mentioned groove remains after an over-etching process as will be explained later.

Subsequently, as shown in FIGS. 3A to 3E, surfaces of the grooves exposed from the opening portions of the first mask layer are thermally-oxidized by ISSG (In Site Stream Generation) to form a silicon oxide film (not shown). Thereafter, a second silicon nitride film 18 is formed over the silicon oxide film by a LP-CVD (Low Pressure-Chemical Vapor Deposition) method. The second silicon nitride film 18 has enough vertical thickness to fill the groove in the cell array region. However, the second silicon nitride film 18 need not fully fill the groove in the peripheral region.

Then, as shown in FIGS. 3A to 3E, the second silicon nitride film 18 is selectively removed by a wet-etching process with a heated phosphoric acid (H₃PO₄). At this time, the second silicon nitride film 18 with a predetermined vertical thickness remains in a bottom portion of the groove in the cell array region. However, the second silicon nitride film 18 in the groove in the peripheral region is fully removed.

Next, as shown in FIGS. 4A to 4E, the second silicon oxide film 19 is formed by an HDP-CVD (High Density Plasma-Chemical Vapor Deposition) method over the entire surface of the semiconductor substrate 10. Then, a surface of the second silicon oxide film 19 is polished by a CMP (Chemical Mechanical Polishing) method until an upper surface of the above-mentioned first silicon nitride film 12 serving as the stopper is exposed.

Subsequently, as shown in FIGS. 5A to 5E, the second silicon oxide film 19 is selectively removed by a wet-etching process with hydrofluoric acid so that the top level of the second silicon oxide film 19 equals the top level of the semiconductor substrate 10. Then, the first silicon nitride film 12 is removed by a wet-etching process with heated phosphorous acid (H₃PO₄). Thus, an element isolation insulating film, which includes the above-mentioned second silicon nitride film 18 and the above-mentioned second silicon oxide film 19, is formed in the element isolation grooves. The above-mentioned element isolation regions and the above-mentioned active regions defined by the element isolation regions are formed. The element isolation regions and the active regions are alternately arranged and extend in the first direction.

Next, as shown in FIGS. 6A to 6E, a second mask layer is formed over the entire surface of the semiconductor substrate. The second mask layer includes a third silicon nitride film 20, a second amorphous carbon film 21, a second oxynitride film 22, a third silicon oxide film 23, and a second anti-reflective (BARC) film 24 which are stacked in this order. Then, a second photoresist (PR) film is formed over the second mask layer 25, and a second resist pattern 25 is formed while the second photoresist film 25 is patterned by a lithography process. The second resist pattern 25 has openings at positions corresponding to the positions of buried gate electrode trenches, namely, grooves each crossing the above-mentioned element isolation regions.

Subsequently, as shown in FIGS. 7A to 7E, the second mask layer is patterned by an anisotropic dry etching process with the second resist pattern 25 as a mask. At this time, although the second resist pattern 25 is removed from the second mask layer with the progression of the dry etching process, the shape of the second resist pattern 25 is transferred onto the second mask layer. Thus, the second mask layer can be patterned according to the shape of the second resist pattern 25. Furthermore, the second mask layer is also removed with the progression of the dry etching process while the shape of the second resist pattern 25 is transferred from an upper layer to a lower layer. For this reason, when the patterning of the second mask layer finishes, all the second anti-reflective (BACR) film 24, the third silicon oxide film 23, and the second silicon oxynitride film 22 are perfectly removed. The second mask layer, which includes the patterned second amorphous carbon film 21 and the patterned third silicon nitride film 20, remains so that the second mask layer has holes at positions for forming the above-mentioned buried gate electrode trenches.

Next, as shown in FIGS. 7A to 7E, only the above-mentioned second silicon oxide film 19 exposed to the holes is selectively removed by an anisotropic selective etching process with the pattern second mask layer as a mask to form the above-mentioned buried gate electrode trenches in the element isolation regions. Under the circumstances, the silicon nitride film 18 in the cell array serves as an etching stopper.

Subsequently, as shown in FIGS. 7A to 7E, only a surface layer (silicon layer) of the semiconductor substrate 10 exposed to the holes is selectively removed by an anisotropic selective etching process with the patterned second mask layer. In this event, the surface layer (silicon layer) of the semiconductor substrate 10 maintains a position higher than a height of the silicon nitride film 18 in the cell array. Thus, a fin portion formed in the surface layer (silicon layer) of the semiconductor substrate 10 in the cell array is formed so as to protrude between the grooves upwardly. Accordingly, the top level of the fin portion is higher than the bottom level of the grooves in the element isolation regions, and is lower than the level of an upper surface of the active regions (i.e. the level of the upper surface of the semiconductor substrate 10).

Next, as shown in FIG. 8, the second amorphous carbon film 21 is removed.

Then, as shown in FIG. 9, the surface of the buried gate electrode trenches exposed to the holes of the second mask layer are thermally-oxidized by ISSG (In Site Steam Generation) to form a gate insulation film 26 made of a silicon oxide film.

Thereafter, as shown in FIG. 10, a titanium nitride (TiN) film 27 is deposited. Then, as shown in FIG. 11, an amorphous silicon film 28 is deposited. Subsequently, as shown in FIG. 12, a tungsten (W) film 29 is deposited. Therefore, a conductive film, which includes the titanium nitride (TiN) film 27, the amorphous silicon 28, and the tungsten (W) film 29 which are stacked over in this order, is formed over the entire surface of the semiconductor substrate 10.

Next, as shown in FIG. 13, an upper surface of the conductive film is polished by a CMP (Chemical Mechanical Polishing) process until the upper surface of the above-mentioned third silicon nitride film 20 serving as the stopper is exposed.

Then, as shown in FIG. 13, the conductive film, which fills the above-mentioned buried gate electrode trenches, is etched to make the conductive film with a predetermined thickness remain in bottom portions of the buried gate electrode trenches. Herein, the predetermined thickness of the conductive film means a thickness such that the conductive film covers at least the upper surface of the fin portions (see, FIG. 15D), and that the top level of the conductive film is lower than the level of the upper surface of the active regions (i.e. the upper surface of the semiconductor substrate 10) at most (see, FIG. 15B).

Next, as shown in FIG. 13 and FIGS. 14A to 14E, a cap insulating film 31 is formed over the entire surface of the semiconductor substrate 10 and then an annealing treatment is subjected. In this exemplary embodiment, a BPSG (Boron Phosphor Silicate Glass) film is used as the cap insulating film 31 and the annealing treatment of about 600° C. is subjected after forming the BPSG film. Thus, a buried gate electrode 30, which includes the titanium nitride (TiN) film 27, a silicon film 28a after heat treatment, and the tungsten (W) film 29 which are stacked, is formed.

Herein, by the annealing treatment about 600° C., the silicon film 28a having a thickness between 1 nm and 3 nm changes so that fine-grained agglomerated objects are scattered at portions where they are originally formed.

Thereafter, an upper surface of the cap insulating film (the BPSG film) 31 is polished by a CMP (Chemical Mechanical Polishing) process until the upper surface of the above-mentioned third silicon nitride film 30 serving as the stopper is exposed.

Subsequently, as shown in FIGS. 15A to 15E, the cap insulating film 31 is selectively removed by a wet etching process with hydrofluoric acid (HF) so that the top level of the cap insulating film 31 equals the top level of the semiconductor substrate 10. Thereafter, the third silicon nitride film 20 is removed by a wet etching process with heated phosphorous acid (H₃PO₄).

Next, as shown in FIGS. 16A to 16E, 17A, 17B, and 17F, an n-type impurity, such as phosphorous, is ion-implanted at a low concentration into the active regions exposed between the cap insulating film 31. Thus, impurity diffusion layers 32 are formed in the both active regions which sandwich the above-mentioned buried gate electrode 30. In the impurity diffusion layers 32, one becomes a drain region while another becomes a source region.

Subsequently, as shown in FIGS. 18A, 18B, and 18F, a first interlayer insulating film (a first insulating interlayer film) 33 is formed, and thereafter the first interlayer insulating film (the first insulating interlayer film) 33 is selectively removed by means of a lithography and dry etching technique which is conventionally known to form bit contact holes 34 for connecting to bit lines.

Next, as shown in FIGS. 19A, 19B, and 19F, bit contact plugs 35 are formed so as to fill in the bit contact holes 34, and then the bit lines 36 are formed on the bit contact plugs 35.

Subsequently, as shown in FIGS. 20A, 20B, and 20F, a second interlayer insulating film (a second insulating interlayer film) 37 is formed so as to cover an upper surface of the first interlayer insulating film (the first interlayer insulating film) 33 and the bit lines 36, and then the second interlayer insulating film (the second insulating interlayer film) 37 is etched to form capacitor contact holes. Thereafter, storage node contact plugs 38 are formed so as to fill in the capacitor contact holes.

Next, as shown in FIGS. 21A, 21B, and 21F, tungsten nitride (WN) and tungsten (W) are deposited in order to form a stacked film, and then the stacked film is patterned to form storage node contact pads 39. Thereafter, a stopper nitride film 40 is formed so as to cover the storage node contact pads 39. Thereafter, contact holes for penetrating the stopper nitride film 40 on the storage node contact pads 39 are formed, and then lower electrodes 41 for capacitors are formed, for example, using titanium nitride or the like so as to cover an upper surface of the exposed storage node contact pads 39.

Subsequently, as shown in FIG. 22, a capacitor insulating film 42 is formed so as to cover the lower electrodes 41. The capacitor insulating film 42 may be, for example, zirconium oxide (ZrO₂), aluminum oxide (Al₂O₃), hafnium oxide (HfO₂), or a stacked layer of them. Then, an upper electrode 43 for the capacitors is formed, for example, by using titanium nitride or the like so as to cover an upper surface of the capacitor insulating film 42. In the manner which is described above, the capacitors each comprising the lower electrode 41, the capacitor insulating film 42, and the upper electrode are formed.

Although illustration is not made, wiring layers are formed over the semiconductor substrate 10 through the capacitors. Therefore, a memory cell of the DRAM is completed.

Although the buried gate electrode 30 comprises the titanium nitride (TiN) film 27, the silicon film 28a, and the tungsten (W) film 29 which are stacked in this order in the above-mentioned exemplary embodiment, the present invention is not limited thereto and may adopt various modified examples which will presently be described.

### MODIFIED EXAMPLES

A first film made of a first metal which is nitrided may be used instead of the titanium nitride (TiN) film 27, an intervention film made of a second metal which is silicided may be used in place of the silicon film 28a, and a second film made of a third metal may be used in lieu of the tungsten (W) film 29.

In this event, each of the first through the third metals may be a high-melting metal or a refractory metal. The high-melting metal may be selected from a group consisting of tungsten, cobalt, titanium, nickel, molybdenum, and tantalum.

In the manner which is described above, according to the exemplary embodiment (the modified examples) of the present invention, it is possible to suppress a resistance increase of the buried gate electrode. This is because this invention uses, as the buried gate electrode, a stacked film comprising a first film made of first metal nitride, an intervention film made of silicon or of second metal silicide, and a second film made of third metal in this order. As a result, this invention produces the effect of resolving a problem of a switching rate delay in a memory device and of moving to finer design rules.

While the invention has been particularly shown and described with reference to exemplary embodiments thereof, the invention is not limited to these embodiments. It will be understood by those of ordinary skill in the art that various changes in form and details may be made therein without departing from the spirit and scope of the present invention as defined the claims.

### INDUSTRIAL APPLICABILITY

This invention can be applied to buried gate electrodes of general products such as a PRAM (Phase-Change Random Access Memory), a ReRAM (Resistive Random Access Memory) and so on without limiting to the buried gate electrodes of the DRAM.

What is claimed is:

1. A semiconductor device comprising:
a semiconductor substrate;
a trench formed on the semiconductor substrate;
an insulating film formed on a side wall of the trench; and
an electrode formed on the insulating film, the electrode comprising a first film made of a first metal which is nitrided, an intervention film made of a silicon or of a second metal which is silicided, and a second film made of a third metal in this order.

2. The semiconductor device as claimed in claim 1, wherein the intervention film has a film thickness between 1 nm and 3 nm, both inclusive.

3. The semiconductor device as claimed in claim 1, wherein the first film, the intervention film, and the second film comprise films which are annealed.

4. The semiconductor device as claimed in claim 1, wherein the first metal comprises a high-melting metal.

5. The semiconductor device as claimed in claim 1, wherein each of the second metal and the third metal comprises a high-melting metal.

6. The semiconductor device as claimed in claim 4, wherein the high-melting metal is selected from a group consisting of tungsten, cobalt, titanium, nickel, molybdenum, and tantalum.

7. The semiconductor device as claimed in claim 5, wherein the high-melting metal is selected from a group consisting of tungsten, cobalt, titanium, nickel, molybdenum, and tantalum.

8. The semiconductor device as claimed in claim 1, wherein further comprises:
a plurality of active regions; and
an element isolation region enclosing the plurality of active regions,
wherein the electrode comprises a wire straddling the element isolation region and at least one of the active regions.

9. The semiconductor device as claimed in claim 1, wherein a most upper surface of the electrode is lower than a most upper surface of the semiconductor substrate.

10. A semiconductor device comprising:
a semiconductor substrate;
first and second trenches which are formed on the semiconductor substrate and which extend in a first direction;
a first film made of a first metal which is nitrided, the first film being formed on side walls of the first and second trenches;
an intervention film which is formed on the side walls of the first and second trenches and which is formed on the first film, the intervention film being made of a silicon or of a second metal which is silicided;
a second film formed on the side walls of the first and second trenches, the second film being made of a third metal different from the first metal; and
a cap insulating film covering the first film, the intervention film, and the second film, the cap insulating film filling in upper portions of the first and second trenches.

11. The semiconductor device as claimed in claim 10, further comprising an insulating film between the side walls of the first and second trenches and the first film.

12. The semiconductor device as claimed in claim 10, wherein a most upper surface of the second film is lower than a most upper surface of the semiconductor substrate.

13. The semiconductor device as claimed in claim 10, wherein further comprises:
a plurality of active regions extending in a second direction different from the first direction; and
an element isolation region enclosing the plurality of active regions,
wherein the first and second trenches simultaneously cross at least one of the active regions.

14. The semiconductor device as claimed in claim 13, further comprising a contact plug formed on a most upper surface of the active region sandwiched between the first and second trenches.

15. The semiconductor device as claimed in claim 10, wherein the intervention film has a film thickness between 1 nm and 3 nm, both inclusive.

16. The semiconductor device as claimed in claim 10, wherein the first film, the intervention film, and the second film comprise films which are annealed.

17. The semiconductor device as claimed in claim 10, wherein the first metal comprises a high-melting metal.

18. The semiconductor device as claimed in claim 10, wherein each of the second metal and the third metal comprises a high-melting metal.

19. The semiconductor device as claimed in claim 17, wherein the high-melting metal is selected from a group consisting of tungsten, cobalt, titanium, nickel, molybdenum, and tantalum.

20. The semiconductor device as claimed in claim 18, wherein the high-melting metal is selected from a group consisting of tungsten, cobalt, titanium, nickel, molybdenum, and tantalum.
